(19) United States
(12) Patent Application Publication
(10) Pub. No.: US 2012/0025247 A1
(43) Pub. Date: Feb. 2, 2012

(54) COMPONENT FOR LIGHT-EMITTING DEVICE, LIGHT-EMITTING DEVICE AND PRODUCING METHOD THEREOF

(75) Inventors: Yasunari OOYABU, Osaka (JP); Toshitaka NAKAMURA, Osaka (JP); Hironaka FUJII, Osaka (JP); Hisataka ITO, Osaka (JP)

(73) Assignee: NITTO DENKO CORPORATION, Osaka (JP)

(21) Appl. No.: 13/182,064

(22) Filed: Jul. 13, 2011

(30) Foreign Application Priority Data
Jul. 27, 2010 (JP) 2010-167880

(51) Int. Cl. H01L 33/60

(52) U.S. Cl. 257/98; 438/27; 257/E33.06

(57) ABSTRACT

A component for a light-emitting device includes a sealing resin layer that is capable of sealing in a light emitting diode, a fluorescent layer that is formed on one face of the sealing resin layer and is capable of emitting fluorescent light, and a reflection layer that is provided on the other face of the sealing resin layer so as to avoid a region where the sealing resin layer seals in the light emitting diode and is capable of reflecting the light.

### CROSS-REFERENCE TO RELATED APPLICATION

The present application claims priority from Japanese Patent Application No. 2010-167880 filed on Jul. 27, 2010, the contents of which are hereby incorporated by reference into this application.

### BACKGROUND OF THE INVENTION

1. Field of the Invention

The present invention relates to a component for a light-emitting device, a light-emitting device, and a producing method thereof.

2. Description of Related Art

Conventionally, as a phosphor that receives blue light and emits yellow light, a YAG (yttrium aluminum garnet) based phosphor has been known. When the blue light is applied to the YAG based phosphor, white light can be obtained by color mixing of the applied blue light and the yellow light that the YAG based phosphor emits. Therefore, a white light emitting diode that is capable of obtaining white light, for example, by covering a blue light emitting diode with a YAG based phosphor to color mix blue light from the blue light emitting diode and yellow light of the YAG based phosphor has been known.

As the white light emitting diode, for example, a light-emitting device including a board, a semiconductor light-emitting device, and a phosphor ceramic board has been known (ref: for example, Japanese Unexamined Patent Publication No. 2010-27704).

There has been proposed that in the light-emitting device, for example, a reflection layer that is capable of reflecting light is provided on the board so as to avoid the semiconductor light-emitting device in order to reflect the light that the semiconductor light-emitting device and the phosphor ceramic board emit to improve the extraction efficiency of light. Furthermore, there has been proposed that, for example, a space between the semiconductor light-emitting device and the reflection layer, and the phosphor ceramic board is sealed in by a transparent sealing resin and the like.

### SUMMARY OF THE INVENTION

However, in the production of the light-emitting device, usually the reflection layer and the semiconductor light-emitting device are first formed on the board and then the sealing resin is provided on the board, the reflection layer, and the semiconductor light-emitting device. Thereafter, the phosphor ceramic board is disposed thereon. Therefore, there is a disadvantage that the production process of the light-emitting device is complicated.

It is an object of the present invention to provide a component for a light-emitting device with which simplification of light-emitting device production processes is achieved, a light-emitting device in which the component for a light-emitting device is used, and a method for producing the light-emitting device.

A component for a light-emitting device of the present invention includes a sealing resin layer that is capable of sealing in a light emitting diode, a fluorescent layer that is formed on one face of the sealing resin layer and is capable of emitting fluorescent light, and a reflection layer that is provided on the other face of the sealing resin layer so as to avoid a region where the sealing resin layer seals in the light emitting diode and is capable of reflecting the light.

In the component for a light-emitting device of the present invention, it is preferable that the reflection layer is formed with a pattern on the entire region excluding the region where the sealing resin layer seals in the light emitting diode.

A light-emitting device of the present invention includes the above-described component for a light-emitting device.

It is preferable that the light-emitting device of the present invention includes a circuit board to which external electric power is supplied, a light emitting diode that is electrically connected onto the circuit board and emits light based on electric power from the circuit board, a housing that is provided on the circuit board so as to surround the light emitting diode and so that the upper end portion thereof is positioned above the upper end portion of the light emitting diode, and the component for a light-emitting device that is provided on the circuit board so that the sealing resin layer covers the light emitting diode and the fluorescent layer is disposed on the housing.

The method for producing a light-emitting device of the present invention includes the steps of electrically connecting a light emitting diode onto a circuit board to which external electric power is supplied; providing a housing on the circuit board so as to surround the light emitting diode and so that the upper end portion thereof is positioned above the upper end portion of the light emitting diode; and providing the above-described component for a light-emitting device on the circuit board so that the sealing resin layer covers the light emitting diode and the fluorescent layer is disposed on the housing.

The component for a light-emitting device of the present invention includes the fluorescent layer, the sealing resin layer, and the reflection layer, so that in the production of the light-emitting device, the fluorescent layer, the sealing resin layer, and the reflection layer can be provided at once instead of each being separately provided.

Therefore, according to the component for a light-emitting device of the present invention, the light-emitting device of the present invention using the component for a light-emitting device of the present invention, and further the producing method of the light-emitting device of the present invention, the light-emitting device can be produced more easily and reliably.

### BRIEF DESCRIPTION OF THE DRAWINGS

FIG. 1 shows the other face view of a first embodiment of a component for a light-emitting device of the present invention.

FIG. 2 shows an A-A sectional view of the component for a light-emitting device shown in FIG. 1.

FIG. 3 shows process drawings for illustrating one embodiment of a method for producing the component for a light-emitting device shown in FIG. 1:

(a) illustrating a step of forming a fluorescent layer,

(b) illustrating a step of forming a sealing resin layer on the other face of the fluorescent layer, and

(c) illustrating a step of forming a reflection layer on the other face of the sealing resin layer.

FIG. 4 shows a flow view for illustrating one embodiment of a method for producing the fluorescent layer shown in FIG. 1.

FIG. 5 shows a schematic configuration view of one embodiment of a light-emitting device of the present invention including the component for a light-emitting device shown in FIG. 1.

FIG. 6 shows schematic process drawings for illustrating a method for producing the light-emitting device shown in FIG. 5:

(a) illustrating a step of providing a light emitting diode on a circuit board and electrically connecting the light emitting diode to the circuit board,

(b) illustrating a step of providing a housing on the circuit board, and

(c) illustrating a step of providing the component for a light-emitting device on the circuit board so that the sealing resin layer covers the light emitting diode and the fluorescent layer is disposed on the housing.

FIG. 7 shows a schematic sectional view of a second embodiment of the component for a light-emitting device of the present invention.

FIG. 8 shows a schematic configuration view of a third embodiment of the component for a light-emitting device of the present invention.

FIG. 9 shows a schematic configuration view of a fourth embodiment of the component for a light-emitting device of the present invention.

FIG. 10 shows a graph obtained in Test Example 1.

### DETAILED DESCRIPTION OF THE INVENTION

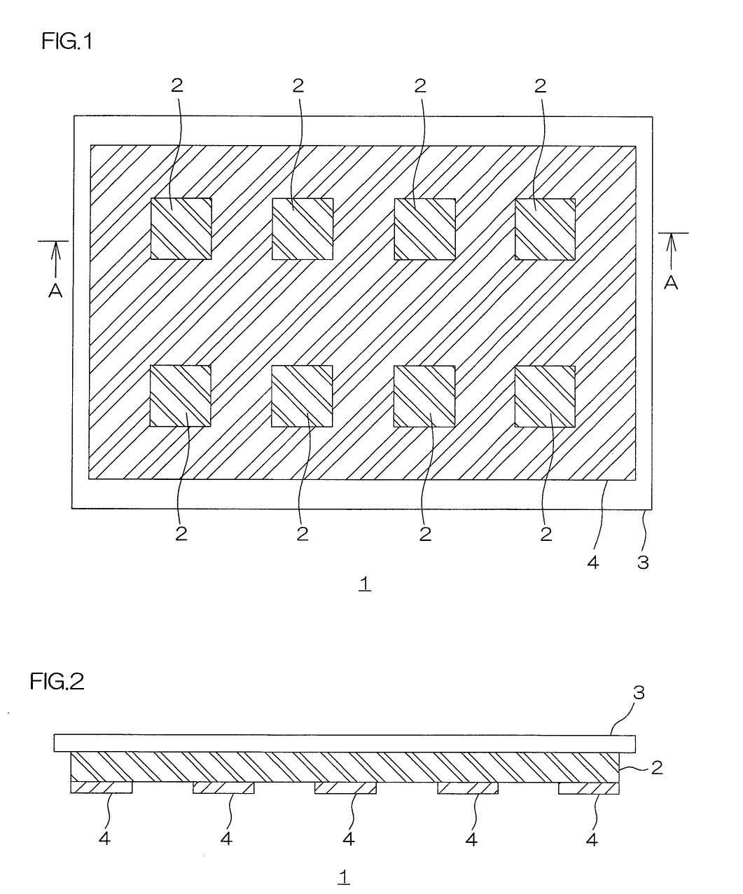

FIG. 1 shows the other face view of a first embodiment of a component for a light-emitting device of the present invention. FIG. 2 shows an A-A sectional view of the component for a light-emitting device shown in FIG. 1.

In FIGS. 1 and 2, a component 1 for a light-emitting device includes a sealing resin layer 2, a fluorescent layer 3 formed on one face of the sealing resin layer 2, and a reflection layer 4 formed on the other face of the sealing resin layer 2.

The sealing resin layer 2 is a resin layer that is provided so as to seal in a light emitting diode 13 (described later) in a light-emitting device 11 (described later) and is formed into a generally rectangular flat plate shape in plane view and is made from, for example, a resin that is capable of transmitting light.

A resin that can be used in the sealing resin layer 2 is capable of transmitting light and sealing in the light emitting diode 13 (described later) without particular limitation and a known thermosetting resin can be used.

In particular, examples of the thermosetting resin include silicone resin, epoxy resin, acrylic resin, and urethane resin. A preferable example is a silicone resin from the viewpoint of durability (thermal resistance, light resistance).

These thermosetting resins can be used alone or in combination of two or more.

In addition, a preferable example of the thermosetting resin includes a thermosetting resin that is excellent in flexibility and conformability so as to prevent damage to the light emitting diode 13 (described later) and a wire 18 (described later) when the component 1 for a light-emitting device is provided on the light-emitting device 11 (described later).

In particular, examples of the thermosetting resin include a thermosetting resin whose storage elastic modulus is low in an uncured state (or in a semi-cured state) (for example, 100 Pa or less) and a thermosetting resin that is excellent in flexibility in a cured state (for example, a gel-like state in a cured state).

Furthermore, from the viewpoint of workability, a preferable example of the thermosetting resin includes a silicone resin that is in a liquid state before being cured (A stage) and in a gel-like state in a semi-cured state (B stage) and is capable of forming an elastomer or a hard resin after being completely cured (C stage).

When such thermosetting resin is used, damage to the light emitting diode 13 (described later) and the wire 18 (described later) can be prevented and the component 1 for a light-emitting device can be provided on the light-emitting device 11 (described later) by allowing the sealing resin layer 2 to be in a semi-cured state. In addition, the light emitting diode 13 (described later) can be reliably sealed in by completely curing the sealing resin layer 2 thereafter.

In particular, examples of the thermosetting resin include a condensation reaction type silicone resin and an addition reaction type silicone resin. When the reaction is stopped before the entire curing reaction ends, these silicone resins can be formed in a semi-cured state.

In addition, a preferable example of the thermosetting resin includes a curable silicone resin in multiple steps (for example, two steps) (silicone resin that is cured by two or more reaction systems). In particular, an example of the thermosetting resin includes a thermosetting resin compound that contains both-ends silanol type silicone resin, silicon compound containing alkenyl group, organohydrogensiloxane, condensation catalyst, and hydrosilylation catalyst.

When the curable silicone resin in multiple steps is used as the thermosetting resin, a silicone resin in a semi-cured state can be obtained at relatively low temperature (less than 150° C.).

The storage elastic modulus (25° C.) of the thermosetting resin in an uncured state is, from the viewpoint of sealing in the light emitting diode 13 (described later), for example, 1.0×10⁶ Pa or less, or preferably 1.0×10² Pa or less. The storage elastic modulus (25° C.) of the thermosetting resin after being heated at 200° C. for one hour is, for example, 1.0×10⁶ Pa or more, or preferably 1.0×10⁷ Pa or more.

The sealing resin layer 2 is formed so that its height (thickness) is higher (thicker) than the height (including the height of the wire 18 (described later)) from one face of a circuit board 12 (described later) to one face of the light emitting diode 13 (described later) so as to seal in the light emitting diode 13 (described later). In particular, the thickness of the sealing resin layer 2 is, though different according to the mounting method, for example, 0.2 to 5 mm.

In particular, the fluorescent layer 3 is, with respect to the sealing resin layer 2, formed into a slightly larger similar shape than that of the sealing resin layer 2 in plane view and is formed so that the circumference end portion of the fluorescent layer 3 is exposed from the sealing resin layer 2.

The fluorescent layer 3 is a layer that is capable of emitting fluorescent light and transmitting light and is formed into a slightly larger generally rectangular flat plate shape in plane view than that of the sealing resin layer 2. The fluorescent layer 3 is, in the light-emitting device 11 (described later), provided on one face of the sealing resin layer 2 so as to absorb the light generated from the light emitting diode 13 (described later) to emit fluorescent light.

The fluorescent layer 3 contains a phosphor that is excited by absorbing a part of all of the light whose wavelength is in the range of 350 to 480 nm as an exciting light, and emits fluorescent light whose wavelength is longer than that of the exciting light, for example, in the range of 500 to 650 nm. In particular, examples of the fluorescent layer 3 include a resin that contains a phosphor and a phosphor ceramic (phosphor ceramic plate).

The phosphor contained in the fluorescent layer 3 is selected appropriately in accordance with the wavelength of the exciting light. When, as an exciting light, for example, light of a near-ultraviolet light emitting diode (wavelength in the range of 350 to 410 nm) or light of a blue light emitting diode (wavelength in the range of 400 to 480 nm) is selected, examples of the phosphor include garnet type phosphor having a garnet type crystal structure such as Y₃Al₅O₁₂:Ce (YAG (yttrium aluminum garnet):Ce), (Y, Gd)₃Al₅O₁₂:Ce, Tb₃Al₃O₁₂:Ce, Ca₃Sc₂Si₃O₁₂:Ce, and Lu₂CaMg₂(Si, Ge)₃O₁₂:Ce; silicate phosphor such as (Sr, Ba)₂SiO₄:Eu, Ca₃SiO₄Cl₂:Eu, Sr₃SiO₅:Eu, Li₂SrSiO₄:Eu, and Ca₃Si₂O₇:Eu; aluminate phosphor such as CaAl₁₂O₁₉:Mn and SrAl₂O₄:Eu; sulfide phosphor such as ZnS:Cu,Al, CaS:Eu, CaGa₂S₄:Eu, and SrGa₂S₄:Eu; oxynitride phosphor such as CaSi₂O₂N₂:Eu, SrSi₂O₂N₂:Eu, BaSi₂O₂N₂:Eu, and Ca-α-SiAlON; nitride phosphor such as CaAlSiN₃:Eu and CaSi₅N₈:Eu; and fluoride-based phosphor such as K₂SiF₆:Mn and K₂TiF₆:Mn.

These phosphors can be used alone or in combination of two or more.

Garnet type phosphor is preferably used as the phosphor.

The absorption rate of the exciting light of the phosphor can be usually adjusted by the doping amount of rare earth element that is added to the phosphor as an activating agent. The relation between the activating agent and the absorption rate differs according to the kind of the constituent element of the phosphor, the heat treatment temperature in calcination (sintering) to be described later, and the like. In the case of YAG:Ce, for example, the additive amount of Ce is, for example, 0.01 to 2.0 atom % as a substituted yttrium basis.

A preferable example of the fluorescent layer 3 includes a phosphor ceramic (phosphor ceramic plate) from the viewpoint of heat dissipation.

That is, in the fluorescent layer 3, its temperature rises, for example, due to heat generation of the phosphor, so that its luminous efficiency may be reduced. However, the phosphor ceramic (phosphor ceramic plate) has excellent heat dissipation, so that the temperature rise of the fluorescent layer 3 can be prevented with the use of the phosphor ceramic (phosphor ceramic plate) and excellent luminous efficiency can be ensured.

A preferable example of the fluorescent layer 3 (phosphor ceramic) includes a transparent and non-scattering (not scattering light) ceramic (translucent ceramic) from the viewpoint of preventing the loss of the light generated from the light emitting diode 13 (described later) and the phosphor by scattering.

The translucent ceramic is, though not particularly limited, for example, formed by removing various light scattering sources such as a void (gap) and impurities in the phosphor ceramic to improve translucency.

In an isotropic crystal material such as YAG and the like, there is no refractive index difference due to crystal orientation, so that a transparent and non-scattering ceramic (translucent ceramic) can be obtained even in multi-crystalline ceramic as in single crystal.

The fluorescent layer 3 (phosphor ceramic) can have a certain amount of light diffusion characteristics without becoming completely transparent from the viewpoint of improving the extraction efficiency of fluorescent light and uniformizing the radiation pattern of fluorescent light.

A known method such as forming a void (gap) and impurities in the phosphor ceramic is used to have light diffusion characteristics. In addition, for example, when the phosphor is YAG:Ce, a material (for example, alumina and the like) that has different refractive index from the YAG:Ce is added therein to form a different phase, so that the light diffusion characteristics can be controlled.

The total luminous transmittance (light diffusion characteristics) of the fluorescent layer 3 (phosphor ceramic) is appropriately controlled according to the optical design. To be specific, the total luminous transmittance (diffuse transmittance) is, for example, 40% or more, or preferably 50% or more, and usually 90% or less.

The total luminous transmittance (diffuse transmittance) of the fluorescent layer 3 can be measured, using an integrating sphere and the like, by a known method. However, the phosphor absorbs light of a specific wavelength, so that the luminous transmittance is measured in the wavelength region excluding the specific wavelength, that is, the wavelength region of visible light (for example, 550 to 800 nm in the case of YAG:Ce) excluding the exciting wavelength in which the phosphor does not substantially show absorption.

The fluorescent layer 3 can be formed in a single-layer structure and furthermore, though not shown, can also be formed in a multi-layer structure in which a plurality (two or more) of layers are laminated.

The thickness (the sum of the thickness of each of the layers in the case of multi-layer structure) of the fluorescent layer 3 is in the range of, for example, 100 to 1000 μm, or preferably 200 to 700 μm, or more preferably 300 to 500 μm.

When the thickness of the fluorescent layer 3 (phosphor ceramic) is below the above-described lower limit, there may be a case where the production of the fluorescent layer 3 (phosphor ceramic) becomes difficult and the handleability in the production thereof deteriorates for the characteristics of the ceramic material of being fragile and easy to break while showing a high degree of hardness.

When the thickness of the fluorescent layer 3 (phosphor ceramic) is above the above-described upper limit, there may be a case where the fluorescent layer 3 (phosphor ceramic) in dicing and the like has poor workability and poor economic efficiency.

In the fluorescent layer 3 (phosphor ceramic), a desired color tone of light is obtained by adjusting the thickness thereof and the above-described absorption rate of the exciting light of the phosphor.

The thermal conductivity of the fluorescent layer 3 is, for example, 5 W/m·K or more, or preferably 10 W/m·K or more from the viewpoint of heat dissipation.

The reflection layer 4 is a layer that is capable of reflecting light and is provided on the other face of the sealing resin layer 2 so as to avoid a region where the sealing resin layer 2 seals in the light emitting diode 13 (described later).

In particular, the reflection layer 4 is formed with a pattern on the entire region excluding the regions where the sealing resin layer 2 seals in the light emitting diodes 13 (described later) and in the regions where the sealing resin layer 2 seals in the light emitting diodes 13 (described later), openings having a generally rectangular shape in plane view are formed.

In particular, as shown in FIG. 1, for example, the reflection layer 4 is formed into the same size and shape as those of the sealing resin layer 2 in plane view. In the reflection layer 4, a plurality of the openings that are arranged in alignment in a plurality of lines (two lines in FIG. 1) and in a plurality of rows (four rows in FIG. 1) are formed at spaced intervals to each other.

The reflection layer 4 is formed by, for example, filling a transparent resin with a filler that has a different refractive index from the resin.

An example of the resin includes a resin having white diffuse reflection characteristics in which there is substantially no light absorption and examples thereof include epoxy resin, silicone resin, acrylic resin, and urethane resin. A preferable example is a silicone resin from the viewpoint of durability (thermal resistance, light resistance).

These resins can be used alone or in combination of two or more.

The filler is not particularly limited and a preferable example is a filler that is white, not absorbing visible light, and having insulating characteristics.

A preferable example of the filler includes the filler that has a large refractive index difference from the above-described resin from the viewpoint of improving the diffuse reflectance.

In particular, examples of the filler include alumina, aluminum nitride, titanium oxide, barium titanate, potassium titanate, barium sulfate, barium carbonate, zinc oxide, magnesium oxide, boron nitride, silica, silicon nitride, gallium oxide, gallium nitride, and zirconium oxide.

These fillers can be used alone or in combination of two or more.

The shape of the filler is not particularly limited and a filler having various shapes such as sphere, needle, plate, and particle in a hollow state can be used.

The average particle size of the filler is, for example, 100 nm to 10 p.m.

The average particle size can be measured by, for example, an electron microscope method, a laser diffraction method, a specific surface area analyzing method (BET method), and the like.

The additive amount of the filler with respect to the above-described resin is in the range of, for example, 10 to 85 volume %, or preferably 20 to 70 volume %, or more preferably 30 to 60 volume %.

When the additive amount of the filler is below the above-described range, there may be a case where a high reflectance is difficult to obtain while the thickness of the reflection layer 4 becomes thick in order to obtain enough diffuse reflectance.

When the additive amount of the filler is above the above-described range, there may be a case where the workability in forming the reflection layer 4 is poor and the mechanical strength of the reflection layer 4 is reduced.

The thickness of the reflection layer 4 is, for example, 50 to 500 μm.

The diffuse reflectance (wavelength: 400 to 800 nm) of the reflection layer 4 is in the range of, for example, 80% or more, or preferably 90% or more, or more preferably 95% or more, and usually 99.9% or less.

When the diffuse reflectance is below the above-described lower limit, there may be a case where the light generated from the fluorescent layer 3 and the light emitting diode 13 (described later) is absorbed, so that the extraction efficiency of the light is reduced.

The diffuse reflectance of the reflection layer 4 is adjusted, for example, by adjusting the thickness of the reflection layer 4 and the additive amount of the filler.

The diffuse reflectance can be obtained by, for example, as follows: the resin added with the filler at the same blend ratio as that for the reflection layer 4 is applied on a glass substrate and the like to form a film having a desired thickness; and the reflectance of the formed film is measured.

In addition, though not shown, the component 1 for a light-emitting device, for example, can include a release liner so as to cover and protect the reflection layer 4 (and the sealing resin layer 2 as required).

Examples of the release liner include a plastic film such as polyethylene film, polypropylene film, polyethylene terephthalate film and polyester film, and a porous material such as paper, fabric, and nonwoven fabric.

A preferable example of the release liner includes a plastic film.

The thickness of the release liner is not particularly limited and is, for example, 5 to 100 μm.

The release liner can be obtained, for example, as a commercially available product and to be specific, as the commercially available product, for example, MRX-100 (biaxially-oriented polyester film, 100 μm in thickness, manufactured by Mitsubishi Polyester Film Inc.) and the like is used.

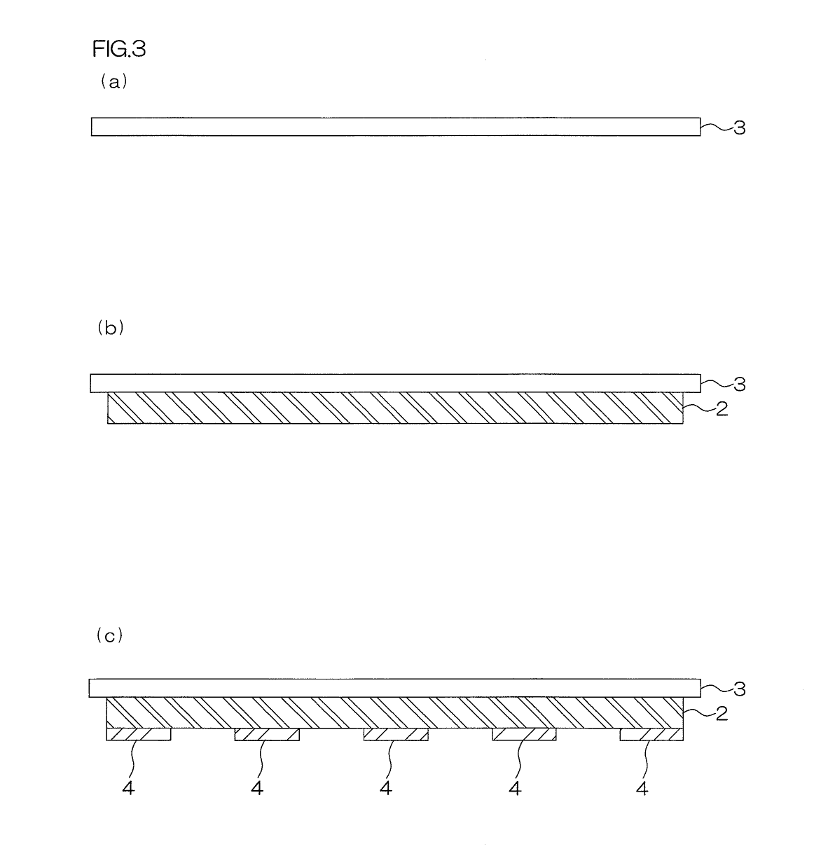

FIG. 3 shows process drawings for illustrating one embodiment of a method for producing the component for a light-emitting device shown in FIG. 1.

Next, a method for producing the above-described component 1 for a light-emitting device is described with reference to FIG. 3.

In this method, as shown in FIG. 3 (a), the fluorescent layer 3 is first formed.

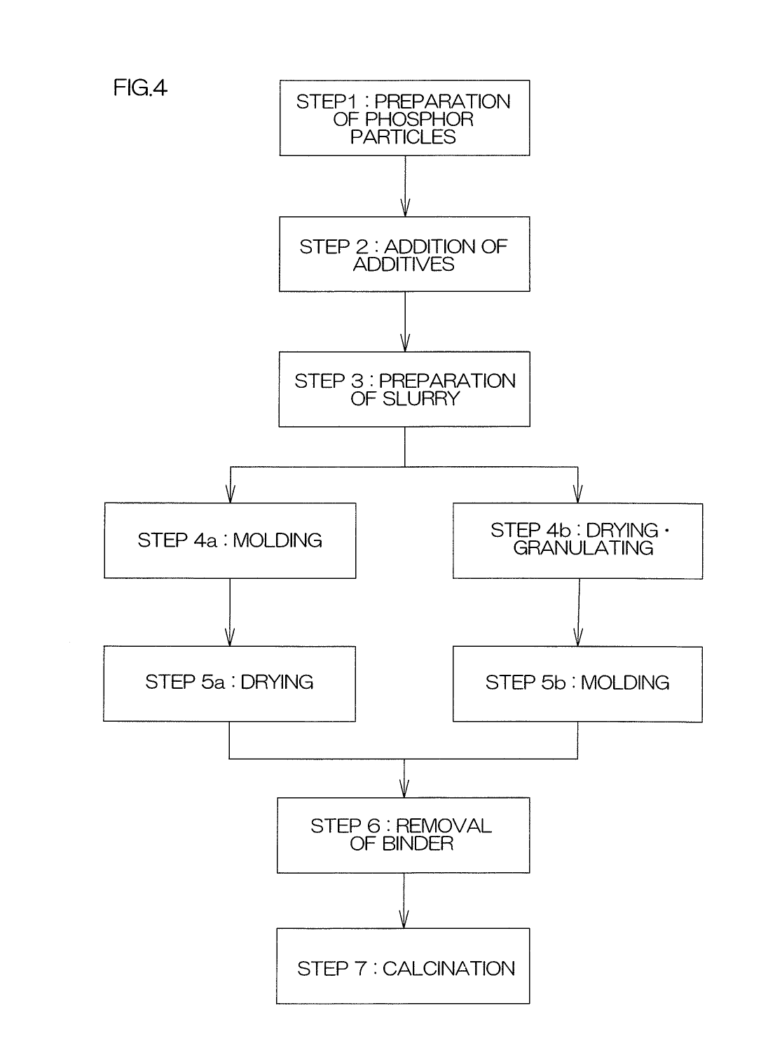

FIG. 4 shows a flow view for illustrating one embodiment of a method for producing the fluorescent layer shown in FIG. 1.

A method for producing the fluorescent layer 3 (phosphor ceramic) is first described with reference to FIG. 4.

In this method, as shown in FIG. 4, particles of the above-described phosphor (including material particles that are raw materials for the phosphor: hereinafter referred to as phosphor particles) are first prepared (step 1), and an additive such as a known binder resin, dispersant, sintering additive, and the like is added into the phosphor particles (step 2), to be wet blended in the presence of a solvent to obtain a slurry solution (step 3).

In this method, an example of the phosphor particles includes the phosphor particles whose average particle size is preferably 50 nm or more and 10 μm or less, or more preferably 1.0 μm or less, or even more preferably 0.5 μm or less.

In this method, the additive amount of the binder resin for giving formability (that is, necessary for maintaining the shape after being formed) increases or decreases according to the specific surface area of the phosphor particles.

Therefore, when the average particle size of the phosphor particles is below the above-described lower limit, there may be a case where the additive amount of the binder resin increases while the solid content ratio of the fluorescent layer 3 decreases.

On the other hand, when the average particle size is not less than the above-described lower limit, it is not necessary to increase the additive amount of the additives (for example, binder resin, dispersant, and the like) or the solvent, so that the solid content ratio of the formed product can be sufficiently increased and furthermore, it is possible to prevent the damage to flowability of a slurry solution caused by the increase of the specific surface area.

As a result, it is possible to increase the density after being sintered to be described later, so that the dimension change at sintering can be reduced to prevent warpage of the fluorescent layer 3 (phosphor ceramic).

Furthermore, when the average particle size is not more than the above-described upper limit, it is possible to increase the density of the fluorescent layer 3 (phosphor ceramic). As a result, it is possible to keep the sintering temperature low for obtaining a dense sintered body and to reduce the generation of the void (gap) after being sintered.

When the fluorescent layer 3 causes a volume change accompanied with a change in crystal structure at the time of sintering (described later) or when the fluorescent layer 3 contains a volatile component such as a residual organic substance (for example, the above-described additive), the phosphor particles that are temporarily calcined as required to be preliminarily phase-transited to a desired crystal phase or, for example, the phosphor particles whose density, purity, and the like are increased by a known method can be used from the viewpoint of obtaining a dense sintered body.

When the phosphor particles include coarse particles whose size are significantly larger than the average particle size of the phosphor particles, the coarse particles may become a generation source of voids. Thus, for example, the observation of presence or absence of the coarse particles is performed with an electron microscope and the coarse particles can be removed by a classification process and the like as required.

The average particle size of the phosphor particles can be measured by a BET (Brunauer-Emmett-Teller) method that is known as a specific surface area analyzing method, a laser diffraction method, direct observation with an electron microscope, and the like.

The additives (binder resin, dispersant, sintering additive, and the like) and the solvent are not particularly limited as long as they can be decomposed and removed by sintering (heating) to be described later, and known additives can be used.

The device that is used in wet blending is not particularly limited and a known dispersing device such as a variety of mixers, ball mills, or bead mills is used.

In this method, the viscosity of the obtained slurry solution is adjusted by a known method as required. Thereafter, the viscosity-adjusted solution is molded into a ceramic green sheet by tape casting using a doctor blade, extrusion molding, and the like (step 4a), to then be dried (step 5a).

Alternatively, for example, the slurry solution is dried and granulated by a spray drying method and the like (step 4b), to thereby prepare dry particles that contain the binder resin. Thereafter, the obtained dry particles can be molded by a pressing method and the like using a mold (step 5b).

In this method, the obtained molded product is heated in the air at, for example, 400 to 800° C. using an electric furnace so as to pyrolyze and remove an organic component such as a binder resin and a dispersant to perform the binder-removing treatment (step 6) and then furthermore, is sintered (fully calcined) (step 7).

The fluorescent layer 3 (phosphor ceramic) is obtained in this manner.

In this method, the sintering conditions (calcining atmosphere, heating temperature, heating duration, and the like) differ according to the phosphor material used therein. When the phosphor is, for example, YAG:Ce, the conditions are as follows: the calcining atmosphere of, for example, in a vacuum, in an inert gas atmosphere such as Ar, or in a reducing gas (hydrogen and hydrogen/nitrogen mixed gas); the sintering temperature of, for example, 1500 to 1800° C.; and the sintering duration of, for example, 0.5 to 24 hours.

When the molded product is sintered in a reducing atmosphere, for example, carbon particles can also be put into an electric furnace added with a reducing gas so as to improve the reducing characteristics.

The temperature rising speed at sintering is, for example, 0.5 to 20° C./min.

When the temperature rising speed is not less than the above-described lower limit, there is no need to require an extreme amount of time for calcination, so that the productivity can be improved.

When the temperature rising speed is not more than the above-described upper limit, rapid growth of crystal grains (grains) can be prevented, so that the void (gap) generation can be suppressed. In particular, it is possible to prevent that grain growth is caused before the void (gap) is filled in to leave the void (gap).

In addition, the molded product can be sintered (fully calcined), for example, by a hot isostatic pressing sintering method (HIP method) under increased pressure so as to improve the density and translucency of the sintered body (phosphor ceramic).

When the molded product (ceramic green sheet and the like) is in a block-like state, after being sintered, the obtained fluorescent layer 3 (phosphor ceramic) can be cut out in a desired size.

Next, in this method, as shown in FIG. 3 (b), the sealing resin layer 2 is formed on the other face of the fluorescent layer 3.

In the formation of the sealing resin layer 2, for example, when a thermosetting resin that is in a gel-like state in a cured state is used, the thermosetting resin is prepared as a solution in an uncured state and the solution is coated on the other face of the fluorescent layer 3 by a known method and is heated to be cured.

The heating conditions are as follows: the heating temperature of, for example, 60 to 150° C., or preferably 80 to 120° C. and the heating duration of, for example, 1 to 30 minutes, or preferably 1 to 20 minutes.

In this way, the sealing resin layer 2 in a cured state (in a gel-like state) can be formed on the other face of the fluorescent layer 3.

Next, in this method, as shown in FIG. 3 (c), the reflection layer 4 is formed on the other face of the sealing resin layer 2.

In the formation of the reflection layer 4, though not shown, for example, the reflection layer 4 is separately produced with the above-described pattern and the obtained reflection layer 4 is attached to the sealing resin layer 2.

A known pattering method can be used for the production of the reflection layer 4. In particular, for example, a resin solution in which the above-described filler is dispersed is coated on a release film with a fixed thickness and is cured to form the reflection layer 4 in a sheet state. The coating method at this time is not particularly limited and, for example, a doctor blade, an applicator, and the like can be used.

In addition to the above-described method, by using another method such as an extrusion molding, the resin is cured, so that the reflection layer 4 in a sheet state can also be formed.

In this method, the obtained reflection layer 4 in a sheet state is subjected to the punching process by using a Thomson blade and a puncher that have a predetermined shape, and the like. In this way, the reflection layer 4 can be formed into a predetermined pattern.

When stick (tackiness) is present after the above-described curing, a release liner as a protective layer is laminated to one face of the reflection layer 4 and then the punching process can be performed therein.

Alternatively, the reflection layer 4 can be directly formed into a predetermined pattern by using, for example, a screen printing, a patterning coating, and the like and furthermore, can be processed into a predetermined pattern by using, for example, a carbon dioxide laser and the like.

In this method, the reflection layer 4 that is formed with the pattern in this way is attached to the other face of the sealing resin layer 2 by using a known adhesive and the like as required. The component 1 for a light-emitting device can be obtained in this manner.

In this method, the sealing resin layer 2 in a gel-like state is formed from a thermosetting resin that is in a gel-like state in a cured state. Alternatively, for example, the sealing resin layer 2 in a gel-like state can be formed by allowing a silicone resin and the like that is in a liquid state before being cured (A stage), in a gel-like state in a semi-cured state (B stage), and capable of forming an elastomer or a hard resin after being completely cured (C stage) to be coated on one face of the fluorescent layer 3 to be in a semi-cured state.

In this method, the fluorescent layer 3 is formed as a phosphor ceramic. Alternatively, for example, the fluorescent layer 3 can be obtained as a resin that contains a phosphor by mixing the phosphor with a known resin to be cured.

In this method, the reflection layer 4 that is separately produced is attached to the sealing resin layer 2. Alternatively, for example, it is possible that the reflection layer 4 is provided (placed) on the uncured sealing resin layer 2 and then the sealing the resin layer 2 is cured. Furthermore, it is possible that, for example, in the formation of the reflection layer 4, when the screen printing or the pattering coating is used, the sealing resin layer 2 is directly formed on one face of the reflection layer 4.

In this method, in the formation of the pattern of the reflection layer 4, the openings having a generally rectangular shape in plane view are formed in the regions where the sealing resin layer 2 seals in the light emitting diodes 13 (described later). Alternatively, the shape of the opening is not particularly limited and, though not shown, a variety of shapes such as a generally circular shape in plane view can be used.

The component 1 for a light-emitting device includes the fluorescent layer 3, the sealing resin layer 2, and the reflection layer 4, so that in the production of the light-emitting device 11 (described later), the fluorescent layer 3, the sealing resin layer 2, and the reflection layer 4 can be provided at once instead of each being separately provided.

Therefore, according to the component 1 for a light-emitting device, the light-emitting device 11 (described later) can be produced more easily and reliably.

In the component 1 for a light-emitting device, the reflection layer 4 is formed with a pattern on the entire region excluding the regions where the sealing resin layer 2 seals in the light emitting diodes 13 (described later), so that the light generated from the fluorescent layer 3 and the light emitting diode 13 can be reflected reliably and efficiently.

In FIG. 3, the sealing resin layer 2 is formed on the other face of the fluorescent layer 3 and the reflection layer 4 is formed on the other face of the sealing resin layer 2. However, in practice, reversed up and down, the sealing resin layer 2 is formed on one face of the fluorescent layer 3 and the reflection layer 4 is formed on one face of the sealing resin layer 2.

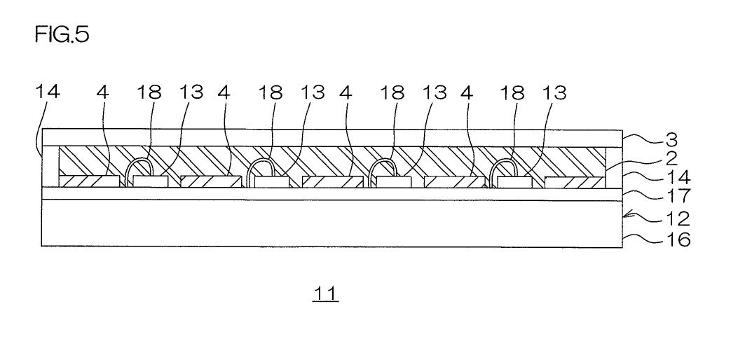

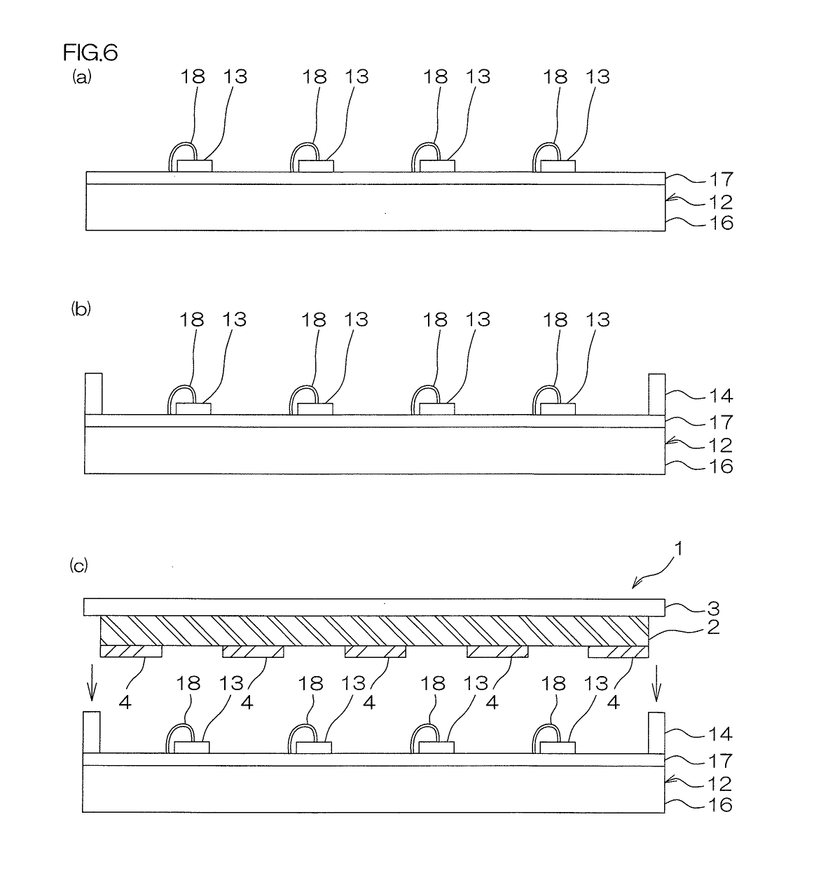

FIG. 5 shows a schematic configuration view of one embodiment of a light-emitting device of the present invention including the component for a light-emitting device shown in FIG. 1. FIG. 6 shows schematic process drawings for illustrating a method for producing the light-emitting device shown in FIG. 5.

In the following, the light-emitting device 11 including the above-described component 1 for a light-emitting device is described with reference to FIG. 5.

In FIG. 5, the light-emitting device 11 includes the circuit board 12, the light emitting diode 13, a housing 14, and the above-described component 1 for a light-emitting device and is formed as a remote type light-emitting device in which the circuit board 12 and the light emitting diode 13 are wire bonded to each other with the fluorescent layer 3 of the component 1 for a light-emitting device and the light emitting diode 13 spaced apart from each other.

The circuit board 12 includes a base board 16 and a wiring pattern 17 formed on the upper face of the base board 16. External electric power is supplied to the wiring pattern 17 of the circuit board 12.

The base board 16 is formed into a generally rectangular flat plate shape in plane view and is formed from a metal such as aluminum, a ceramic such as alumina, a polyimide resin, and the like.

The wiring pattern 17 electrically connects a terminal of the light emitting diode 13 to a terminal (not shown) of a power source (not shown) for supplying electric power to the light emitting diode 13. The wiring pattern 17 is formed from a conductive material such as copper and iron.

A plurality (two lines×four rows) of the light emitting diodes 13 are provided on the base board 16 at spaced intervals to each other, for example, via a known solder and the like. Each of the light emitting diodes 13 is electrically connected (wire bonded) to the wiring pattern 17 via the wires 18. The light emitting diodes 13 emit light based on electric power from the circuit board 12.

The housing 14 is provided to stand upward from the upper face of the wiring pattern 17 so that the upper end portion of the housing 14 is positioned above the upper end portion of the light emitting diodes 13. The housing 14 is formed into a generally rectangular frame shape in plane view so as to surround the light emitting diodes 13 in plane view.

The housing 14 is formed from, for example, a resin added with a filler or a ceramic. The reflectance of the housing 14 with respect to the light from the light emitting diode 13 is set to be, for example, 70% or more, or preferably 90% or more, or more preferably 95% or more.

The housing 14 can also be formed as a circuit board with a housing by integrally forming the housing 14 with the circuit board 12 in advance. As a circuit board with a housing, a commercially available product is available. For example, a ceramic multilayer board with cavity (part number: 207806, manufactured by Sumitomo Metal (SMI) Electronics Devices Inc.) is used.

The component 1 for a light-emitting device is provided so that on the circuit board 12, the sealing resin layer 2 covers the light emitting diodes 13 and the fluorescent layer 3 is disposed on the housing 14.

In the following, a method for producing the above-described light-emitting device 11 is described with reference to FIG. 6.

In this method, as shown in FIG. 6 (a), on the circuit board 12 to which external electric power is supplied, a plurality (two lines×four rows) of the light emitting diodes 13 are first provided to electrically connect the light emitting diodes 13 to the circuit board 12 with the wires 18.

Next, in this method, as shown in FIG. 6 (b), the housing 14 is provided on the circuit board 12.

In particular, the housing 14 is arranged so as to surround the light emitting diodes 13 on the circuit board 12 and so that the upper end portion thereof is positioned above the upper end portion of the light emitting diodes 13.

As described above, the housing 14 and the circuit board 12 can also be formed as a circuit board with a housing. In this case, the above-described two steps (ref: FIGS. 6 (a) and (b)) are performed as one step, that is, the step in which the light emitting diodes 13 are provided on the circuit board 12 with the housing 14 to be electrically connected is performed.

Next, in this method, as shown in FIG. 6 (c), the component 1 for a light-emitting device is provided on the circuit board 12 so that the sealing resin layer 2 of the component 1 for a light-emitting device covers the light emitting diodes 13 and the fluorescent layer 3 is disposed on the housing 14.

At this time, the sealing resin layer 2 is in a gel-like state in a cured state as described above, so that when the component 1 for a light-emitting device is provided on the circuit board 12, the sealing resin layer 2 deforms due to the pressing force to come into close contact with the light emitting diodes 13 and the wires 18. In addition, at this time, the sealing resin layer 2 fills in the space between the light emitting diodes 13 and the reflection layer 4 and comes into close contact with one face of the wiring pattern 17 that is exposed from the light emitting diodes 13.

The component 1 for a light-emitting device may be adhered onto the circuit board 12 by an adhesive as required. In this case, the adhesive is not particularly limited and a known adhesive can be used and furthermore, the same material as that for forming the sealing resin layer 2 as described above (for example, thermosetting resin) can also be used.

The light-emitting device 11 in which the light emitting diodes 13 are sealed in and protected by the sealing resin layer 2 can be obtained in this manner.

In the light-emitting device 11, for example, by using a near-ultraviolet light emitting diode, a blue light emitting diode, or the like and also by using the fluorescent layer 3 that generates fluorescent light by using the light from the light emitting diode 13 as an exciting light, the light-emitting device 11 (white light emitting diode) that generates white light can be obtained by color mixing those lights.

In the light-emitting device 11, the combination of the light emitting diode 13 and the fluorescent layer 3 (combination of color mixing) is not limited to the above description and can be appropriately selected in accordance with the necessity and the use.

For example, by using a blue light emitting diode as the light emitting diode 13 and using the fluorescent layer 3 that produces green fluorescent light by using the light from the light emitting diode 13 as an exciting light, the light-emitting device 11 that produces green light (green light emitting diode) can be obtained. Furthermore, the light-emitting device 11 that generates a variety of lights such as pastel colors can be obtained by using the fluorescent layer 3 that produces other lights.

In the above-described embodiment, the sealing resin layer 2 is formed from a thermosetting resin that is in a gel-like state in a cured state. Alternatively, for example, when the sealing resin layer 2 is formed by allowing a silicone resin and the like that is in a liquid state before being cured (A stage), in a gel-like state in a semi-cured state (B stage), and capable of forming an elastomer or a hard resin after being completely cured (C stage) to be coated on one face of the fluorescent layer 3 to be in a semi-cured state, it can further be heated as required to be completely cured.

In the above-described embodiment, the light-emitting device 11 having a plurality (two lines×four rows) of the light emitting diodes 13 is formed. Alternatively, the number of the light emitting diode 13 provided on the light-emitting device 11 is not particularly limited and for example, one light emitting diode 13 can be provided on the light-emitting device 11.

Although not shown, a sealing resin layer can be formed on the component 1 for a light-emitting device so as to cover the fluorescent layer 3 as required and furthermore, for example, a lens having a generally semi-sphere shape (generally dome shape), a micro-lens array sheet, a diffusing sheet, and the like, all of which are formed from a transparent resin such as a silicone resin and the like, can be provided thereon. In this way, it is possible to improve the extraction efficiency of the light of the light-emitting device 11 and control of the directional characteristics and/or the diffusion characteristics thereof.

The above-described component 1 for a light-emitting device is used in the light-emitting device 11.

Therefore, according to the producing method of the light-emitting device 11 and the light-emitting device 11 obtained by the method, the light-emitting device 11 can be produced more easily and reliably.

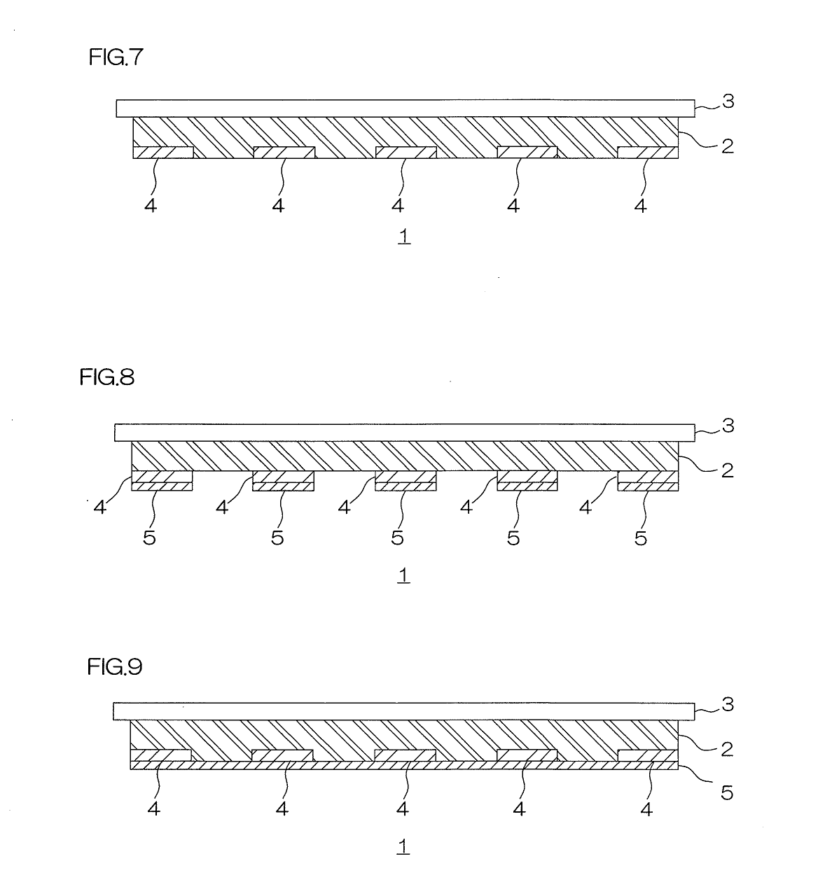

FIG. 7 shows a schematic sectional view of a second embodiment of the component for a light-emitting device of the present invention. In each figure to be described below, the same reference numerals are provided for members corresponding to each of those described above, and their detailed description is omitted.

In the above-described description, the reflection layer 4 is formed on the other face of the sealing resin layer 2. Alternatively, as shown in FIG. 7, the reflection layer 4 can also be formed so as to be buried in the sealing resin layer 2.

In particular, in FIG. 7, in the component 1 for a light-emitting device, the reflection layer 4 is provided so as to be buried in the sealing resin layer 2 on the other face of the sealing resin layer 2, that is, the sealing resin layer 2 is filled in the openings (ref: FIG. 1) that are formed in the reflection layer 4.

In the component 1 for a light-emitting device, the other face of the reflection layer 4 is formed so as to become flush with the other face (the other face of the regions where the reflection layer 4 is not buried) of the sealing resin layer 2.

According to the component 1 for a light-emitting device, the sealing resin layer 2 is filled in the openings (ref: FIG. 1) that are formed in the reflection layer 4, so that the light emitting diodes 13 can be sealed in more reliably by the sealing resin layer 2.

FIG. 8 shows a schematic configuration view of a third embodiment of the component for a light-emitting device of the present invention.

Furthermore, in the component 1 for a light-emitting device, an adhesive layer 5 can be provided on the other face of the reflection layer 4.

In particular, in FIG. 8, in the component 1 for a light-emitting device, the adhesive layer 5 is formed in the same pattern as in the reflection layer 4 and is attached to the other face of the reflection layer 4.

The material used in the adhesive layer 5 is not particularly limited and a known adhesive, a known adhesive sheet, and the like can be used. Furthermore, the same material as that for forming the sealing resin layer 2 as described above (for example, thermosetting resin) can also be used.

According to the component 1 for a light-emitting device, the adhesive layer 5 is provided on the other face of the reflection layer 4, so that the component 1 for a light-emitting device can be fixed on the circuit board 12 more reliably by the adhesive layer 5.

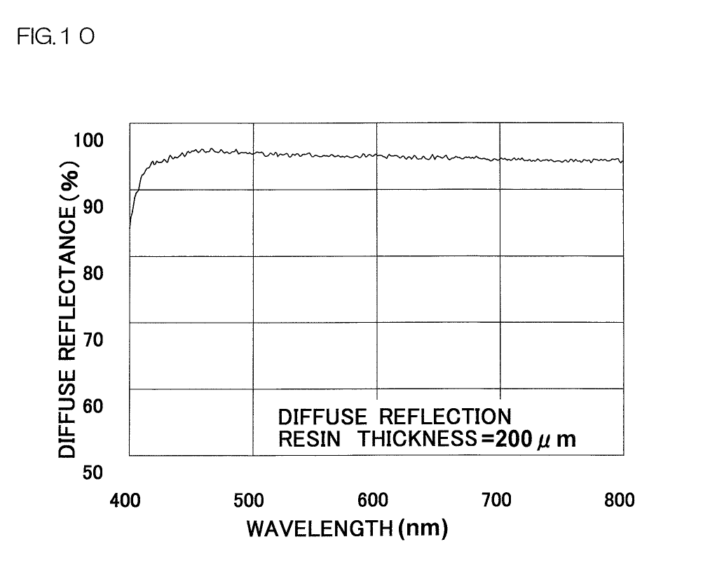

FIG. 9 shows a schematic configuration view of a fourth embodiment of the component for a light-emitting device of the present invention.

In the embodiment shown in FIG. 8, the adhesive layer 5 is formed with a pattern and is provided on the other face of the reflection layer 4. Alternatively, as shown in FIG. 9, the adhesive layer 5 can be provided on the face of the reflection layer 4 exposed from the sealing resin layer 2 and on the other face (the other face of the regions where the reflection layer 4 is not buried) of the sealing resin layer 2 while the reflection layer 4 is formed so as to be buried in the sealing resin layer 2.

In particular, in FIG. 9, in the component 1 for a light-emitting device, the reflection layer 4 is provided on the other face of the sealing resin layer 2 so as to be buried in the sealing resin layer 2, that is, the sealing resin layer 2 is filled in the openings (ref: FIG. 1) that are formed in the reflection layer 4.

In the component 1 for a light-emitting device, the other face of the reflection layer 4 is formed so as to become flush with the other face (the other face of the regions where the reflection layer 4 is not buried) of the sealing resin layer 2.

The adhesive layer 5 is formed into a generally rectangular shape in plane view that is the same size and shape as those of the sealing resin layer 2 in plane view and is attached to the face of the reflection layer 4 exposed from the sealing resin layer 2 and to the other face (the other face of the regions where the reflection layer 4 is not buried) of the sealing resin layer 2.

In the component 1 for a light-emitting device, for example, when the adhesive layer 5 is formed from the same material as that for forming the sealing resin layer 2 as described above (for example, thermosetting resin), the adhesive layer 5 can be used without being cured and the sealing resin layer 2 can be used in a gel-like state in a cured state.

In this case, when the component 1 for a light-emitting device is provided on the circuit board 12, the sealing resin layer 2 and the adhesive layer 5 deform due to the pressing force to come into close contact with the light emitting diodes 13 and the wires 18. In addition, at this time, the sealing resin layer 2 and the adhesive layer 5 fill in the space between the light emitting diodes 13 and the reflection layer 4 and come into close contact with one face of the wiring pattern 17 that is exposed from the light emitting diodes 13.

In this case, the adhesive layer 5 can also be heated to be cured after providing the component 1 for a light-emitting device on the circuit board 12 as required.

In this method, for example, both of the sealing resin layer 2 and the adhesive layer 5 can be in a gel-like state in a cured state.

In this case as well, when the component 1 for a light-emitting device is provided on the circuit board 12, the sealing resin layer 2 and the adhesive layer 5 deform due to the pressing force to come into close contact with the light emitting diodes 13 and the wires 18. In addition, at this time, the sealing resin layer 2 and the adhesive layer 5 fill in the space between the light emitting diodes 13 and the reflection layer 4 and come into close contact with one face of the wiring pattern 17 that is exposed from the light emitting diodes 13.

According to the component 1 for a light-emitting device, the sealing resin layer 2 is filled in the openings (ref: FIG. 1) that are formed in the reflection layer 4, so that the light emitting diodes 13 can be sealed in more reliably by the sealing resin layer 2. Furthermore, the adhesive layer 5 is provided on the face of the reflection layer 4 exposed from the sealing resin layer 2 and on the other face (the other face of the regions where the reflection layer 4 is not buried) of the sealing resin layer 2, so that the component 1 for a light-emitting device can be fixed on the circuit board 12 more reliably by the adhesive layer 5.

Although not shown, when the component 1 for a light-emitting device includes the adhesive layer 5, the above-described release liner can be provided on the other face of the adhesive layer 5.

By providing the release liner on the other face of the adhesive layer 5, the handling of the component 1 for a light-emitting device can be improved and by using the component 1 for a light-emitting device, the light-emitting device 11 can be produced more easily.

### EXAMPLES

While in the following, the present invention is described based on Examples, the present invention is not limited to any of them by no means.

### Production Example 1

### Preparation Example of Phosphor (Material Particles) (Preparation Example of YAG:Ce Phosphor)

The components described below were dissolved in 250 ml of distilled water to prepare 0.4 M of a precursor solution. The details of the components were as follows: 0.14985 mol (14.349 g) of yttrium nitrate hexahydrate, 0.25 mol (23.45 g) of aluminum nitrate nonahydrate, and 0.00015 mol (0.016 g) of cerium nitrate hexahydrate.

The precursor solution was sprayed and pyrolyzed at a speed of 10 ml/min in radio frequency (RF) induction plasma flame using a two-fluid nozzle to obtain inorganic powder particles (material particles).

When the obtained material particles were analyzed by an X-ray diffraction method, a mixed phase of amorphous phase and YAP (YAlO₃) crystal was shown.

The average particle size thereof measured by a BET (Brunauer-Emmett-Teller) method using an automatic specific surface area analyzer (manufactured by Micrometritics Instrument Corp., model Gemini 2365) was about 75 nm.

Next, the obtained material particles were put in a crucible made of alumina and were temporarily calcined at 1200° C. for two hours in an electric furnace to obtain a YAG:Ce phosphor. The crystal phase of the obtained YAG:Ce phosphor showed a single phase of YAG. The average particle size thereof measured by the BET method was about 95 nm.

### Production Example 2

### Production Example of Phosphor Ceramic Plate (YAG-CP)

The components described below were mixed in a mortar to obtain a slurry and methanol was removed from the obtained slurry with a dryer to obtain a dry powder. The details of the components were as follows: 4 g of YAG:Ce phosphor (the average particle size of 95 nm); 0.21 g of poly(vinyl butyl-co-vinyl alcohol co vinyl alcohol) (manufactured by Sigma-Aldrich Co., weight average molecular weight: 90000 to 120000) as a binder resin; 0.012 g of silica powder (manufactured by Cabot Corporation, product name: CAB-O-SIL HS-5) as a sintering additive; and 10 ml of methanol.

700 mg of the dry powder was filled in a uniaxial press mold in the size of 25 mm×25 mm and then was subjected to application of pressure with a load of about 10 tons with a hydraulic pressing machine, so that a plate-like green molded product having a rectangular shape with a thickness of about 350 μm was obtained.

The obtained green molded product was heated up to 800° C. at the temperature rising speed of 2° C./min in the air in a tube electric furnace made of alumina to decompose and remove an organic component such as a binder resin and the like. Subsequently, the inside of the electric furnace was evacuated with a rotary pump and then was heated at 1600° C. for five hours, so that a ceramic plate of YAG:Ce phosphor (YAG-CP) in the size of 20 mm×20 mm with a thickness of about 280 μm was obtained.

The density of the obtained plate measured by Archimedes method was 99.7% with respect to 4.56 g/cm³ in the theoretical density. The total luminous transmittance thereof in the wavelength of 700 nm was 66%.

### Production Example 3

### Production Example of Circuit Board, Light Emitting Diode, and Housing

In the center on a BT (bismaleimide triazine) resin board having a size of 35 mm×35 mm and a thickness of 1.5 mm, blue light emitting diode chips (manufactured by Cree, Inc., part number: C450EX1000-0123, 980 μm×980 μm in size, chip thickness of about 100 μm) were mounted in the following arrangement: a total of four pieces (two lines×two rows) were arranged at 4 mm intervals to each other with two pieces in the longitudinal direction and two pieces in the lateral direction, to thereby produce a blue LED device.

In the blue LED device, its lead was formed of Cu whose face was protected with Ni/Au. The LED chip was die bonded on the lead with a silver paste and an opposing electrode was wire bonded on the lead using gold wires.

A frame (housing) made of glass epoxy (FR4) having a thickness of 0.5 mm, an outer diameter of 25 mm×25 mm, and an inner diameter of 10 mm×10 mm was provided on the blue LED device so as to prevent the resin from flowing out on forming the sealing resin layer and the reflection layer.

### Test Example 1

### Diffuse Reflectance of Reflection Layer

Barium titanate particles (manufactured by SAKAI CHEMICAL INDUSTRY CO., LTD., part number: BT-03, values of absorption specific surface area: 3.7 g/m²) was added into a two-liquid mixed type thermosetting silicone elastomer (manufactured by Shin-Etsu Chemical Co., Ltd., part number: KER 2500) so as to adjust the content of the particles to 55 mass %. Then, the mixture was stirred and mixed well to obtain a coating resin liquid (white resin liquid) for a diffuse reflection resin layer (hereinafter referred to as a reflection layer).

The coating resin liquid was coated on a glass substrate with a thickness of 200 μm using an applicator and then was heated at 100° C. for one hour and at 150° C. for one hour, so that the silicone resin was cured.

The diffuse reflectance of the coating layer was measured, and sufficiently high diffuse reflectance was obtained even with a thickness of 200 μm thereof, showing the reflectance of 90% or more in the visible light range excluding the neighborhood of 400 nm. The relation between the wavelength of light and the diffuse reflectance is shown in FIG. 10.

### Example 1

### Production of Component for Light-Emitting Device and Light-Emitting Device

The coating resin liquid (white resin liquid) used in Test Example 1 was coated on a PET (polyethylene terephthalate) film with a thickness of about 200 μm using an applicator to be cured by being heated at 100° C. for one hour and at 150° C. for one hour, so that a reflection layer was formed.

The reflection layer could be easily peeled off from the PET film by being cured. Next, the peeled piece was cut out into the size of 10 mm×10 mm with a CO₂ laser cutter (manufactured by Universal Laser Systems, Inc., product name: VersaLASER VLS2.30). Furthermore, four holes each having a diameter of about 2 mm were cut out therefrom at 4 mm intervals in accordance with the mounting pattern of the blue light emitting diode in the blue LED device obtained in Production Example 3, so that openings were formed.

The ceramic plate of YAG:Ce phosphor (YAG-CP) obtained in Production Example 2 was subjected to dicing into the size of 12 mm×12 mm and a masking tape of about 1 mm in width was attached to the outer circumference portion of one face thereof (corresponding to FIG. 3 (a)).

A gel-like silicone resin liquid (manufactured by WACKER ASAHIKASEI SILICONE CO., LTD., product name: WACKER SilGel 612) was coated thereon with a thickness of about 350 μm using an applicator and was heated at 80° C. about 10 seconds on a hot plate and then the masking tape was peeled off. Thereafter, the coated one was quickly transferred onto another hot plate whose temperature was set to be at 100° C. and was heated for 15 minutes and the gel-like silicone resin was cured. In this way, a gel-like silicone resin (sealing resin layer in a cured state) was formed on one face of the ceramic plate of YAG:Ce phosphor (fluorescent layer) (corresponding to FIG. 3 (b)).

Next, a separately produced reflection layer was attached onto the gel-like silicone resin (corresponding to FIG. 3 (c)), thereby producing a component for a light-emitting device (corresponding to FIGS. 1 and 2).

Next, the above-described gel-like silicone resin liquid, as an adhesive, was put in drops into the housing of the blue LED device and was spread all over therein. Thereafter, the component for a light-emitting device was pushed lightly to be provided so as to be close contact with the blue LED device so that four punched-out portions correspond to the four respective mounting positions of the blue light emitting diodes. Thereafter, the gel-like silicone resin liquid (adhesive) was cured at 100° C. for 15 minutes, thereby producing a light-emitting device (corresponding to FIG. 5).

### Example 2

### Production of Component for Light-Emitting Device and Light-Emitting Device

A gel-like silicone resin (sealing resin layer in a cured state) was formed on one face of the ceramic plate of YAG:Ce phosphor (fluorescent layer) in the same manner as in Example 1 and a reflection layer that was separately produced was attached thereon.

Thereafter, furthermore, the gel-like silicone resin liquid was coated using an applicator and the openings of the reflection layer were filled with the gel-like silicone resin liquid (sealing resin layer) and the gel-like silicone resin liquid, as an adhesive layer, was coated on the exposed face of the reflection layer and the other face of the sealing resin layer, thereby producing a component for a light-emitting device (corresponding to FIG. 9).

The gap of the applicator was adjusted so that the thickness of the gel-like silicone resin as an adhesive layer was 50 μm or less.

Next, in the same manner as in Example 1, the component for a light-emitting device was provided so as to be close contact with the blue LED device obtained in Production Example 3 so that four punched-out portions correspond to the four respective mounting positions of the blue light emitting diodes. Thereafter, the gel-like silicone resin liquid (adhesive layer) was cured at 100° C. for 15 minutes, thereby producing a light-emitting device.

In Example 1 and Example 2, the reflection layer and the sealing resin layer were preliminarily formed on the fluorescent layer to thereby produce the component for a light-emitting device, so that the light-emitting device could be easily produced with excellent efficiency.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A component for a light-emitting device comprising:
a sealing resin layer that is capable of sealing in a light emitting diode;
a fluorescent layer that is formed on one face of the sealing resin layer and is capable of emitting fluorescent light; and
a reflection layer that is provided on the other face of the sealing resin layer so as to avoid a region where the sealing resin layer seals in the light emitting diode and is capable of reflecting the light.

2. The component for a light-emitting device according to claim 1, wherein
the reflection layer is formed with a pattern on the entire region excluding the region where the sealing resin layer seals in the light emitting diode.

3. A light-emitting device comprising:
a component for a light-emitting device comprising
a sealing resin layer that is capable of sealing in a light emitting diode;
a fluorescent layer that is formed on one face of the sealing resin layer and is capable of emitting fluorescent light; and
a reflection layer that is provided on the other face of the sealing resin layer so as to avoid a region where the sealing resin layer seals in the light emitting diode and is capable of reflecting the light.

4. The light-emitting device according to claim 3, comprising:
a circuit board to which external electric power is supplied;
a light emitting diode that is electrically connected onto the circuit board and emits light based on electric power from the circuit board;
a housing that is provided on the circuit board so as to surround the light emitting diode and so that the upper end portion thereof is positioned above the upper end portion of the light emitting diode; and
the component for a light-emitting device that is provided on the circuit board so that the sealing resin layer covers the light emitting diode and the fluorescent layer is disposed on the housing.

5. A method for producing a light-emitting device comprising the steps of:
electrically connecting a light emitting diode onto a circuit board to which external electric power is supplied;
providing a housing on the circuit board so as to surround the light emitting diode and so that the upper end portion thereof is positioned above the upper end portion of the light emitting diode;
providing a component for a light-emitting device including a sealing resin layer that is capable of sealing in a light emitting diode;
a fluorescent layer that is formed on one face of the sealing resin layer and is capable of emitting fluorescent light; and
a reflection layer that is provided on the other face of the sealing resin layer so as to avoid a region where the sealing resin layer seals in the light emitting diode and is capable of reflecting the light
on the circuit board so that the sealing resin layer covers the light emitting diode and the fluorescent layer is disposed on the housing.
